(19) United States
(12) Patent Application Publication
(10) Pub. No.: US 2014/0216789 A1
(43) Pub. Date: Aug. 7, 2014

(54) SUBSTRATE STRUCTURE

(71) Applicant: LEXTAR ELECTRONICS CORPORATION, Hsinchu (TW)

(72) Inventor: Yen-Chih Chou, Zhubei City (TW)

(21) Appl. No.: 13/933,739

(22) Filed: Jul. 2, 2013

(30) Foreign Application Priority Data
Feb. 5, 2013 (TW) 102104390

(51) Int. Cl. H05K 1/02

(52) U.S. Cl. CPC H05K 1/0204
USPC 174/252

(57) ABSTRACT

A substrate structure includes a heat dissipating plate and a wiring board. The heat dissipating plate includes at least two inward gaps which are symmetrical to each other and disposed at corners of the heat dissipating plate. The wiring board includes a conduction sheet and an insulation sheet. The conduction sheet includes opposite first and second surfaces, an opening which extends through the first and second surfaces, and two symmetrical conduction pins. The conduction pins extend through the conduction sheet and protrude from the second surface. The insulation sheet is disposed on the second surface of the conduction sheet and covers an outer wall of the conduction pins. The substrate structure is formed by aligning the conduction pins with the inward gaps to combine the heat dissipating plate and the wiring board such that a receiving depression is formed between the heat dissipating plate and the opening.

### RELATED APPLICATIONS

This application claims priority to Taiwan Application Serial Number 102104390, filed Feb. 5, 2013, which is herein incorporated by reference.

### BACKGROUND

1. Field of Invention

The embodiment of the present invention relates generally to basic electric elements and, more particularly, to a substrate structure.

2. Description of Related Art

The range of applications for light emitting diodes increased considerably after the successful mass production in Japan of high brightness blue light emitting diodes in 1994. Increases in the production yield rate of light emitting diodes have led to a decrease in the unit production cost thereof, and as a consequence, the demand for light emitting diodes has increased.

In addition, in order to satisfy user demand for light, thin, short, and small electronic devices, the size of light emitting diode packages is getting smaller day by day. However, with respect to the printed circuit board of a light emitting diode package, the heat dissipating part thereof is small due to the overall size limitation of the printed circuit board, thereby making it difficult to dissipate heat generated by a light emitting diode of the light emitting diode package.

Furthermore, again with respect to the printed circuit board of a light emitting diode package, the electric properties of an uncut single body cannot be tested such that it is hard to test the light emitting diode package. There has been much effort in trying to find a solution to the aforementioned problems. Nonetheless, there is still a need to improve the existing apparatuses and techniques in the art.

### SUMMARY

One aspect of the embodiment of the present invention is to provide a substrate structure that includes a heat dissipating plate and a wiring board. The heat dissipating plate includes at least two inward gaps which are symmetrical to each other, wherein the inward gaps are disposed at corners of the heat dissipating plate respectively. The wiring board includes a conduction sheet and an insulation sheet. The conduction sheet includes a first surface and a second surface corresponding in position to the first surface, an opening which extends through the first surface and the second surface, and at least two conduction pins which are symmetrical to each other. The conduction pins extends through the conduction sheet and protrude from the second surface for a distance. The insulation sheet is disposed on the second surface of the conduction sheet and covers an outer wall of a portion of the conduction pins which protrudes from the second surface. The substrate structure is formed by aligning the conduction pins with the inward gaps to combine the heat dissipating plate and the wiring board such that there is a receiving depression formed between the heat dissipating plate and the opening.

As a result, the embodiments of the present invention provide a substrate structure which addresses the problem of heat generated from the light emitting diode being hard to dissipate. That is, with the conventional light emitting diode package, the heat dissipating part of a printed circuit board thereof is small because of the use of a continuous board, and the embodiments of the present invention address this problem. In addition, the embodiments of the present invention provide a substrate structure which addresses the problem difficult testing of the light emitting diode package. That is, with the use of a continuous board in the conventional light emitting diode package, the electric properties of such an uncut single body cannot be tested, and such a problem is addressed by the embodiments of the present invention.

### BRIEF DESCRIPTION OF THE DRAWINGS

The invention can be more fully understood by reading the following detailed description of the embodiments, with reference made to the accompanying drawings as follows:

FIG. 1 schematically shows a diagram of a heat dissipating plate according to embodiments of the present invention.

FIG. 2A schematically shows a top view of a wiring board according to embodiments of the present invention.

FIG. 2B schematically shows a bottom view of a wiring board according to embodiments of the present invention.

FIG. 3A schematically shows a cross-sectional structure along the AA′ line of the heat dissipating plate and the wiring board of FIGS. 1 and 2A according to embodiments of the present invention.

FIG. 3B schematically shows a cross-sectional structure along the AA′ line of the heat dissipating plate and the wiring board of FIGS. 1 and 2A according to embodiments of the present invention.

FIG. 3C schematically shows a cross-sectional structure along the BB′ line of the heat dissipating plate and the wiring board of FIGS. 1 and 2A according to embodiments of the present invention.

FIG. 3D schematically shows a cross-sectional structure along the BB′ line of the heat dissipating plate and the wiring board of FIGS. 1 and 2A according to embodiments of the present invention.

FIG. 4 schematically shows a top view of a substrate structure according to embodiments of the present invention.

### DETAILED DESCRIPTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a,” “an,” and “the” includes plural reference unless the context clearly dictates otherwise. Also, as used in the description herein and throughout the claims that follow, the meaning of “in” includes “in” and “on” unless the context clearly dictates otherwise.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. The use of examples anywhere in this specification, including examples of any terms discussed herein, is illustrative only, and in no way limits the scope and meaning of the invention or of any exemplified term. Likewise, the invention is not limited to various embodiments given in this specification.

As used herein, “around,” “about” or “approximately” shall generally mean within 20 percent, preferably within 10 percent, and more preferably within 5 percent of a given value or range. Numerical quantities given herein are approximate, meaning that the term “around,” “about” or “approximately” can be inferred if not expressly stated.

As used herein, the terms “comprising,” “including,” “having,” “containing,” “involving,” and the like are to be understood to be open-ended, i.e., to mean including but not limited to.

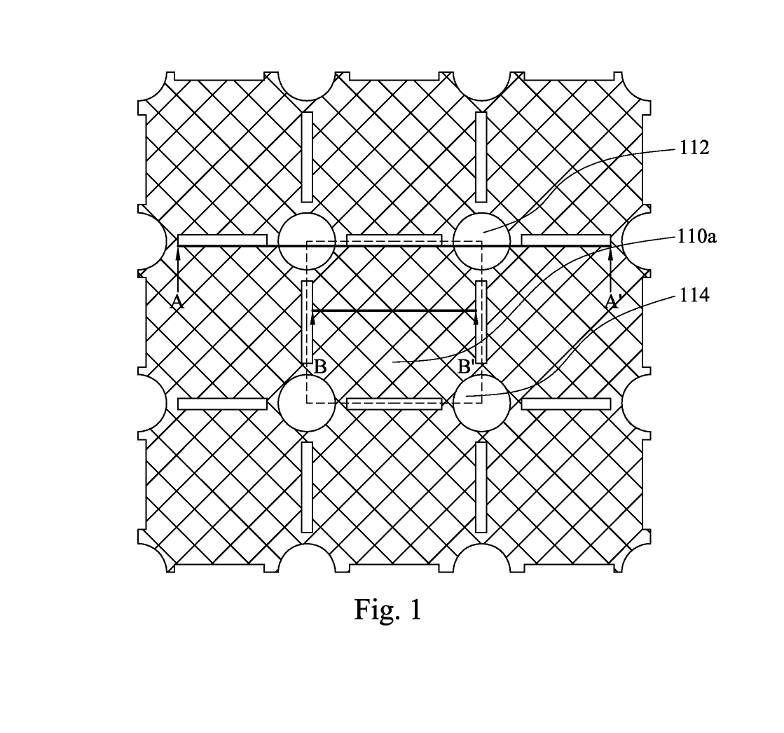

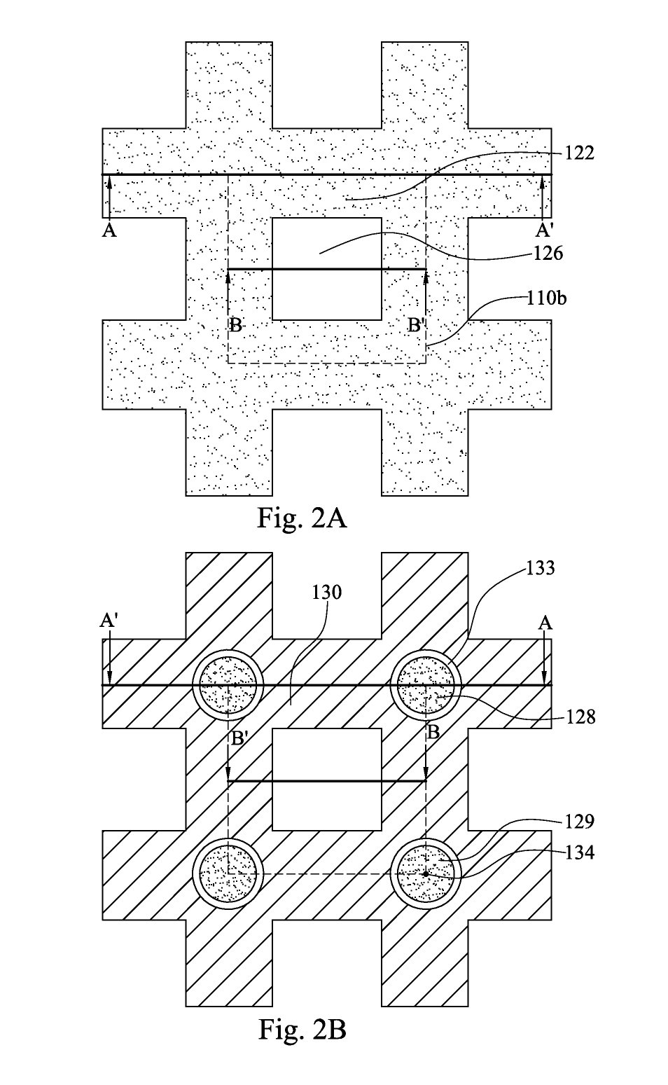

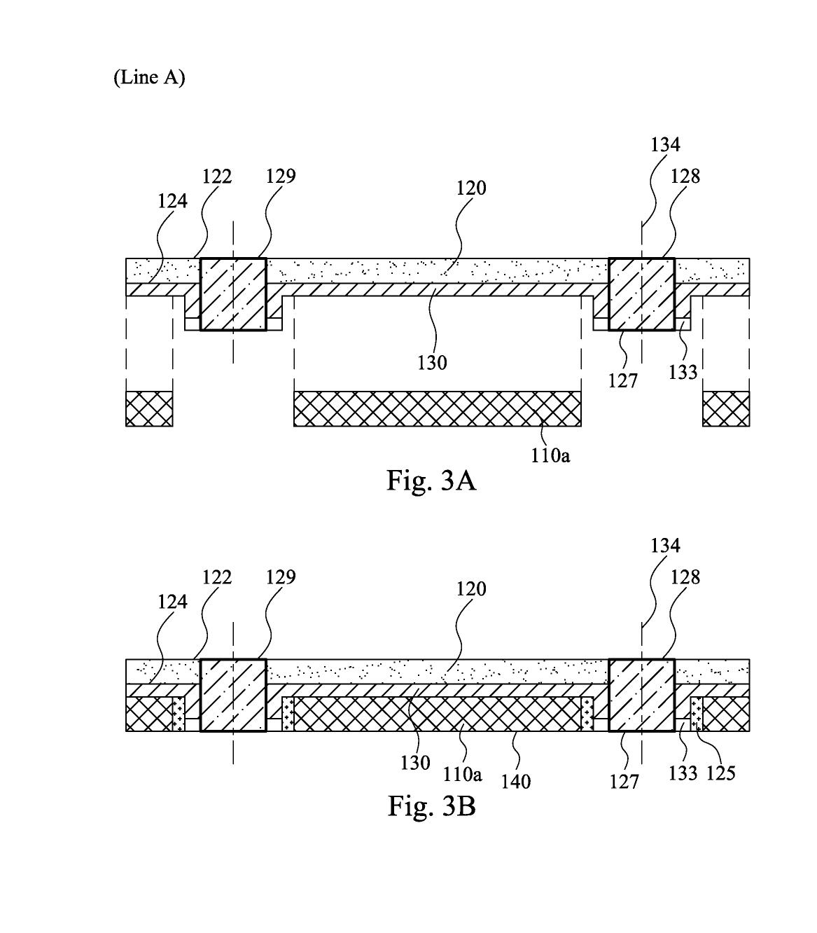

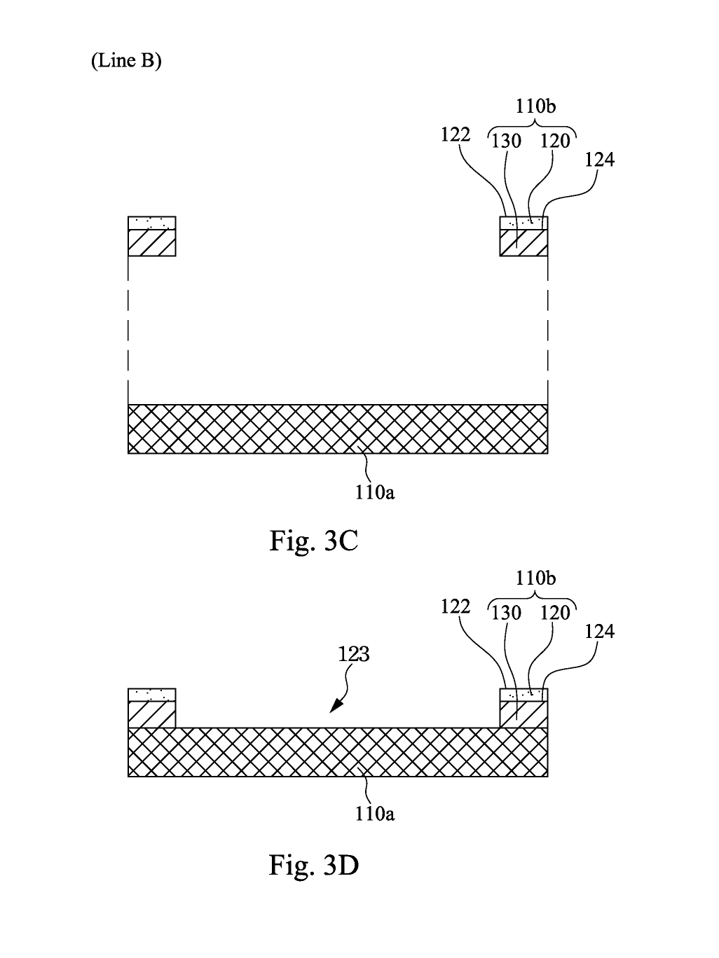

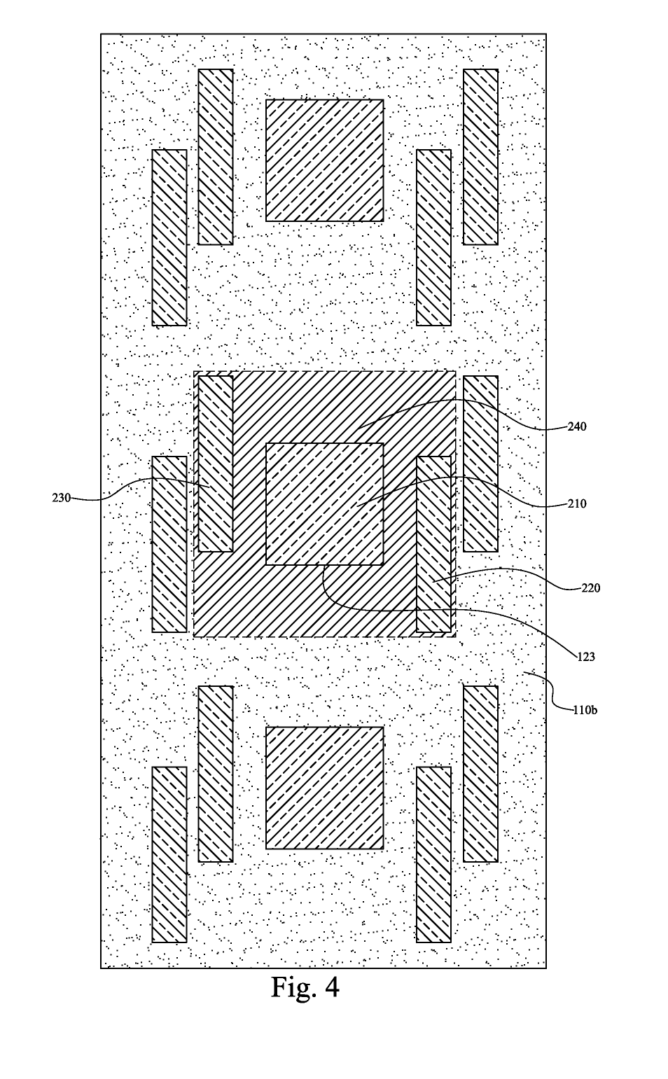

For solving the problems associated with traditional techniques, the embodiments of the present invention provide a substrate structure, and the substrate structure comprises two portions, for example, a heat dissipating plate and a wiring board. With respect to the drawings, most features of the heat dissipating plate and the wiring board are illustrated in FIG. 1 and FIG. 2A to 2B respectively, and other features of the heat dissipating plate and the wiring board are illustrated in FIG. 3A to 3D and FIG. 4. The features of the substrate structure of the embodiments of the present invention will now be described.

The embodiments of the present invention will be described with reference to the drawings by explaining which drawing represents what structure and further by explaining the connection between the structures in each of the drawings such that the substrate structure of the embodiments of the present invention can be easily understood. FIG. 1 schematically shows a diagram of a heat dissipating plate 110a according to embodiments of the present invention, FIG. 2A and 2B schematically and respectively show a top view and a bottom view of a wiring board 110b according to embodiments of the present invention.

FIG. 3A schematically shows a cross-sectional structure along the AA′ line of the heat dissipating plate 110a and the wiring board 110b of FIGS. 1 and 2A according to embodiments of the present invention, and FIG. 3B schematically shows a cross-sectional structure along the AA′ line of the heat dissipating plate 110a and the wiring board 110b of FIGS. 1 and 2A according to embodiments of the present invention. The manner in which the heat dissipating plate 110a and the wiring board 110b are assembled together to form the substrate structure as shown in FIG. 3B can be clearly seen from FIG. 3A.

FIG. 3C schematically shows a cross-sectional structure along the BB′ line of the heat dissipating plate 110a and the wiring board 110b of FIGS. 1 and 2A according to embodiments of the present invention, and FIG. 3D schematically shows a cross-sectional structure along the BB′ line of the heat dissipating plate 110a and the wiring board 110b of FIGS. 1 and 2A according to embodiments of the present invention. Similarly, the manner in which the heat dissipating plate 110a and the wiring board 110b are assembled together to form the substrate structure as shown in 3D can be clearly seen from FIG. 3C. In addition, the top view of the fabricated substrate structure is shown in FIG. 4. As shown in FIG. 4, the substrate structure comprises at least two patterning electrodes 220, 230 which are disposed around the receiving depression, wherein the patterning electrodes are independent of each other, and electrically coupled to the conduction sheet of the wiring board respectively.

With the relation between the structures in each of the drawings understood, the detailed features of the substrate structure of the embodiments of the present invention will now be described.

Referring to FIG. 1, the heat dissipating plate 110a comprises at least two inward gaps 112, 114 which are symmetrical to each other, wherein the inward gaps 112, 114 are disposed at the corners of the heat dissipating plate 110a respectively.

Referring to FIGS. 2A-2B and 3A-3B, the wiring board 110b comprises a conduction sheet 120 and an insulation sheet 130. With respect to the detailed structure of the conduction sheet 120, referring particularly to FIG. 3A, the conduction sheet 120 comprises a first surface 122, a second surface 124, and at least two conduction pins 128, 129. The second surface 124 corresponds in position to the first surface 122, and the conduction pins 128, 129 are symmetrical to each other. As shown in FIG. 2A, the conduction sheet 120 further comprises an opening 126, and the opening 126 extends through the first and second surfaces 122, 124.

As illustrated in FIG. 3B, the conduction pins 128, 129 extend through the conduction sheet 120, and protrude from the second surface 124 of the conduction sheet 120 for a distance. The insulation sheet 130 is disposed on the second surface 124 of the conduction sheet 120 and covers an outer wall of a portion of the conduction pins 128, 129 which protrudes from the second surface 124.

The manner in which the heat dissipating plate 110a and the wiring board 110b are assembled involves aligning each of the conduction pins 128, 129 with one of the inward gaps 112, 114 to combine the heat dissipating plate 110a and the wiring board 110b, and to thereby form the substrate structure such that there is a receiving depression 123 as shown in FIG. 4 formed between the heat dissipating plate 110a and the opening 126. When implementing the embodiment, silver or a high-reflectivity material is further applied to a surface of the receiving depression.

In one embodiment of the present invention, referring to FIG. 3B, each of the conduction pins 128, 129 comprises a bottom surface 127, and the heat dissipating plate 110a comprises a bottom surface 140. The bottom surfaces 127 of the conduction pins 128, 129 and the bottom surface 140 of the heat dissipating plate 110a are on the same plane. In another embodiment of the present invention, each of the conduction pins 128, 129 further comprises an electroplating layer, and the electroplating layer is formed on the bottom surface 127 of the each of the conduction pins 128, 129. Those skilled in the art can selectively electroplate metal on the bottom surface 127 of each of the conduction pins 128, 129 based on actual requirements. In still another embodiment of the present invention, the substrate structure can further comprise an electroplating layer (not shown in the Figures), and the electroplating layer is formed on the heat dissipating plate 110a. Those skilled in the art can selectively electroplate metal on the heat dissipating plate 110a based on actual requirements.

In another embodiment of the present invention, referring back to FIG. 1, the center part marked by a dotted line represents one substrate structure unit of an LED package. It is noted that the area of the heat dissipating plate 110a is about 30% or more of the total area of the substrate structure. However, the scope of the present invention is not limited in this regard, and those skilled in the art can selectively configure the heat dissipating plate 110a such that its area is about 40%, 50%, 60%, 70%, 80%, 90%, or an even a higher percentage of the total area of the substrate structure. Referring to FIG. 2B, in contrast to the unit of the heat dissipating plate 110a, the unit of the wiring board 110b is formed by cutting through the center point of each conduction pin 128, 129, for example, the center point 134. Furthermore, a housing aperture 133 is formed in the area surrounding each of the conduction pins 128, 129. The housing aperture 133 can insulate the heat dissipating plate 110a from the wiring board 110b.

In one embodiment of the present invention, the conduction pins 128, 129 can be composed of metal, copper liquid, oxygen-free copper, silver paste, or a combination thereof. However, the scope of the present invention is not limited in this regard, and those skilled in the art can selectively adopt appropriate material to form the conduction pins 128, 129.

Referring to FIG. 3B, in one embodiment of the present invention, the insulation sheet 130 is adhered to the heat dissipating plate 110a. In another embodiment of the present invention, the substrate structure further comprises an adhesive layer 125, and the adhesive layer 125 is disposed between the conduction pins 128, 129 and the inward gaps 112, 114. The adhesive layer 125 not only can bond the conduction pins 128, 129 and the inward gaps 112, 114 together, but further insulates the conduction pins 128, 129 and the inward gaps 112, 114.

In one embodiment of the present invention, referring back to FIG. 1, the shapes of the inward gaps 112, 114 can be circles, triangles, squares, or the combination thereof, in contrast, the conduction pins 128, 129 match the shape of the inward gaps 112, 114. For instance, if the shape of the inward gap 112 is circle, the conduction pin 128 is a corresponding circle; if the shape of the inward gap 112 is triangle, the conduction pin 128 is a corresponding triangle; if the shape of the inward gap 112 is square, the conduction pin 128 is a corresponding square. However, the scope of the present invention is not limited in this regard, those skilled in the art can selectively adopt appropriate shapes to form the inward gap and form the conduction pin correspondingly.

In one embodiment of the present invention, the heat dissipating plate 110a is composed of copper foil, glass fiber copper clad laminate, or the combination thereof. In addition, white paint or solder mask is further applied to the surface of the heat dissipating plate 110a. In another embodiment, the wiring board 110b is a glass fiber copper clad laminate. Furthermore, white paint or solder mask is further applied to the surface 240 of the wiring board 110b. In still another embodiment of the present invention, silver or high-reflectivity material is further applied to the surface 210 of the containing tank 123. However, the scope of the present invention is not limited in this regard, those skilled in the art can selectively adopt appropriate material to form the heat dissipating plate 110a and the wiring board 110b, and the appropriate material can be applied to the surfaces of the heat dissipating plate 110a, the wiring board 110b, and the containing tank 123.

As shown in FIG. 4, in one embodiment of the present invention, the substrate structure further comprises at least two patterning electrodes 220, 230. The patterning electrodes 220, 230 are disposed around the containing tank 123. With respect to the structure, the patterning electrodes 220, 230 are independent to each other, and electrically coupled to the conduction sheet 120 of the wiring board 110b respectively. In addition, the shape of the patterning electrodes can be square, circuit, or any appropriate form.

Therefore, compared with the conventional art, the invention has at least the following advantages:

1. Compared with the printed circuit board of the light emitting diode package, the heat dissipating part of the substrate structure of the embodiment of the present invention is almost take possession of 30% of the entire substrate structure such that the heat dissipating efficiency of the substrate structure can be increased; and

2. Each units of the substrate structure of the embodiment of the present invention has a wiring board, and accordingly, the electric property of the uncut unit can be tested such that the test efficiency of the industry can be increased.

It will be understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of this invention, and the scope thereof is determined by the claims that follow.

What is claimed is:

1. A substrate structure, comprising:
a heat dissipating plate comprising at least two inward gaps which are symmetrical to each other, wherein the inward gaps are disposed at the corners of the heat dissipating plate respectively ; and
a wiring board comprising:
a conduction sheet comprising a first surface and a second surface corresponding in position to the first surface, an opening which extends through the first and the second surface, and at least two conduction pins which are symmetrical to each other, wherein the conduction pins extend through the conduction sheet and protrude from the second surface for a distance; and
an insulation sheet disposed on the second surface of the conduction sheet and covering an outer wall of a portion of the conduction pins which protrudes from the second surface;
wherein the substrate structure is formed by aligning each of the conduction pins with one of the inward gaps to combine the heat dissipating plate and the wiring board such that there is a receiving depression formed between the heat dissipating plate and the opening.

2. The substrate structure according to claim 1, wherein each of the conduction pins comprises a bottom surface, and the heat dissipating plate comprises a bottom surface, wherein the bottom surfaces of the conduction pins and the bottom surface of the heat dissipating plate are on the same plane.

3. The substrate structure according to claim 2, wherein each of the conduction pins further comprises:
an electroplating layer formed on the bottom surface thereof.

4. The substrate structure according to claim 1, further comprising:
an electroplating layer formed on the heat dissipating plate.

5. The substrate structure according to claim 1, wherein the area of the heat dissipating plate is about 30% or more of the area of the substrate structure.

6. The substrate structure according to claim 1, wherein the conduction pins are composed of metal, copper liquid, oxygen-free copper, silver paste, or a combination thereof.

7. The substrate structure according to claim 1, wherein the insulation sheet is adhered to the heat dissipating plate.

8. The substrate structure according to claim 1, further comprising an adhesive layer which is disposed between the conduction pins and the inward gaps.

9. The substrate structure according to claim 1, wherein the inward gaps are circular, triangular, square, or a combination thereof.

10. The substrate structure according to claim 9, wherein the shape of the conduction pins matches the shape of the inward gaps.

11. The substrate structure according to claim 1, wherein the heat dissipating plate is composed of a copper foil, a glass fiber copper clad laminate, or a combination thereof.

12. The substrate structure according to claim 11, wherein a white paint or a solder mask is further applied to the surface of the heat dissipating plate.

13. The substrate structure according to claim 1, wherein the wiring board is a glass fiber copper clad laminate.

14. The substrate structure according to claim 13, wherein a white paint or a solder mask is further applied to the surface of the wiring board.

15. The substrate structure according to claim 10, wherein silver or a high-reflectivity material is further applied to a surface of the receiving depression.

16. The substrate structure according to claim 1, further comprising:
at least two patterning electrodes disposed around the receiving depression, wherein the patterning electrodes are independent of each other, and electrically coupled to the conduction sheet of the wiring board respectively.
